(19) United States
(12) Patent Application Publication
(10) Pub. No.: US 2025/0343112 A1
(43) Pub. Date: Nov. 6, 2025

(54) FRONT SIDE TO BACKSIDE INTERCONNECTION FOR CFET DEVICES

(71) Applicant: Taiwan Semiconductor Manufacturing Co., Ltd., Hsinchu (TW)

(72) Inventors: Kuan Yu Chen, Hsinchu (TW); Chun-Yen Lin, Hsinchu (TW); Hsin Yang Hung, New Taipei City (TW); Ching-Yu Huang, Hsinchu (TW); Wei-Cheng Lin, Taichung City (TW); Jiann-Tyng Tzeng, Hsinchu (TW); Ting-Yun Wu, Taipei City (TW); Wei-De Ho, Hsinchu (TW); Szuya Liao, Zhubei (TW)

(21) Appl. No.: 19/268,470

(22) Filed: Jul. 14, 2025

Related U.S. Application Data
(63) Continuation of application No. 18/327,998, filed on Jun. 2, 2023.
(60) Provisional application No. 63/485,736, filed on Feb. 17, 2023.
(60) Provisional application No. 63/489,015, filed on Mar. 8, 2023.

(51) Int. Cl. H01L 23/48; H10D 30/67; H10D 64/01; H10D 84/01; H10D 84/03; H10D 84/85

(52) U.S. Cl. CPC H01L 23/481; H10D 30/6729; H10D 64/017; H10D 84/017; H10D 84/0186; H10D 84/038; H10D 84/85

(57) ABSTRACT

A method includes forming a multi-layer stack comprising dummy layers and semiconductor layers located alternatingly, and forming a plurality of dummy gate stacks on sidewalls and a top surface of the multi-layer stack. Two of the plurality of dummy gate stacks are immediately neighboring each other, and have a space in between. A first source/drain region and a second source/drain region are formed in the multi-layer stack, with the second source/drain region overlapping the first source/drain region. The method further includes replacing the plurality of dummy gate stacks with a plurality of replacement gate stacks, replacing a first one of the plurality of replacement gate stacks with a first dielectric isolation region, forming a deep contact plug in the space, forming a front-side via over the deep contact plug, and forming a back-side via under the deep contact plug.

### PRIORITY CLAIM AND CROSS-REFERENCE

This application is a continuation of U.S. patent application Ser. No. 18/327,998, filed on Jun. 2, 2023 and entitled “Front Side to Backside Interconnection for CFET Devices,” which application claims the benefit of U.S. Provisional Application No. 63/489,015, filed on Mar. 8, 2023, and entitled “Front Side to Back Side Connection Structure for CFET Device,” and U.S. Provisional Application No. 63/485,736, filed on Feb. 17, 2023, and entitled “Front Side to Back Side Connection Structure for CFET Device,” which applications are hereby incorporated herein by reference.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (for example, transistors, diodes, resistors, capacitors, etc.) through continual reduction in minimum feature size, which allows more components to be integrated into a given area. As the minimum feature sizes are reduced, however, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of a front-and-back interconnect structure in accordance with some embodiments.

FIG. 2 illustrates the front-side and the backside structures of a power tap cell in accordance with some embodiments.

FIG. 3 illustrates a perspective view of a front-and-back interconnect structure for signal connections in accordance with some embodiments.

FIG. 4 illustrates the front-side and the backside structures of a signal front-and-back interconnect structure in accordance with some embodiments.

FIG. 5 illustrates a circuit diagram of an AND gate in accordance with some embodiments.

FIG. 6 illustrates the front-side and the backside structures of an AND gate in accordance with some embodiments.

FIGS. 7-13 illustrate the cross-sectional views of intermediate stages in the formation of a portion of a front-to-back signal interconnection in accordance with some embodiments.

FIGS. 14A and 14B illustrate the cross-sectional views of a portion of the structure shown in FIG. 13 in accordance with some embodiments.

FIGS. 15-17 illustrate the cross-sectional views of intermediate stages in the formation a front-and-back interconnect structure including epitaxy semiconductor regions in accordance with some embodiments.

FIGS. 18-20 illustrate the front side and backside structures of various front-and-back interconnect structures in accordance with some embodiments.

FIG. 21 illustrates the distribution of power tap cells in accordance with some embodiments.

FIG. 22 illustrates the distribution of power tap cells in accordance with some embodiments.

FIG. 23 illustrates the front-and-back interconnections between cells in accordance with some embodiments.

FIG. 24 illustrates the front-and-back routing of circuits having driver cells in accordance with some embodiments.

FIG. 25 illustrates a process flow for forming a front-and-back interconnect structure in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Front-and-back interconnect structures for Complementary Field-Effect Transistors (CFETs) and the methods of forming the same are provided. In accordance with some embodiments of the present disclosure, the front-and-back interconnect structures include deep contact plugs between gate-replacing structures, which represent several possible structures that may replace original dummy gate structures. The deep contact plugs may be formed in the same processes as the formation of source/drain contact plugs. By forming the deep contact plugs between the gate-replacing structures, the deep contact plugs do not have to cut apart the gate-replacing structures, and power tap cell may be formed smaller without the need of adding extra poly pitches. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

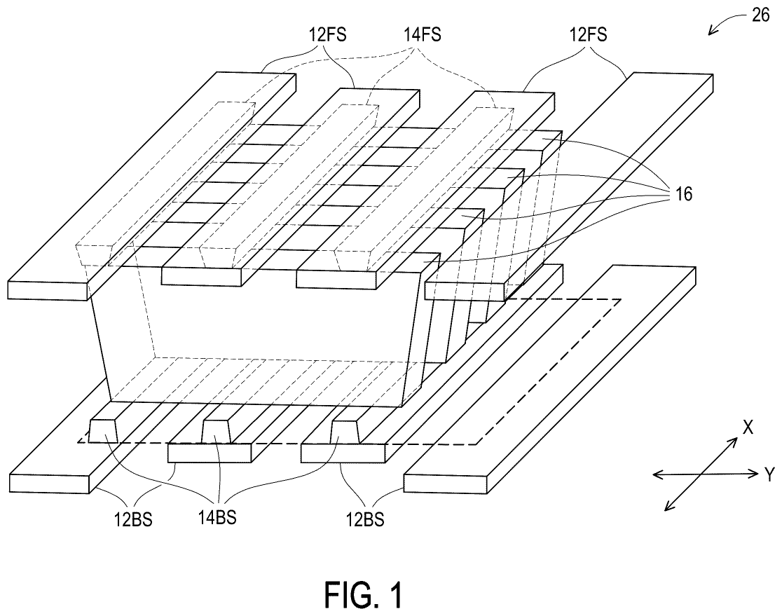

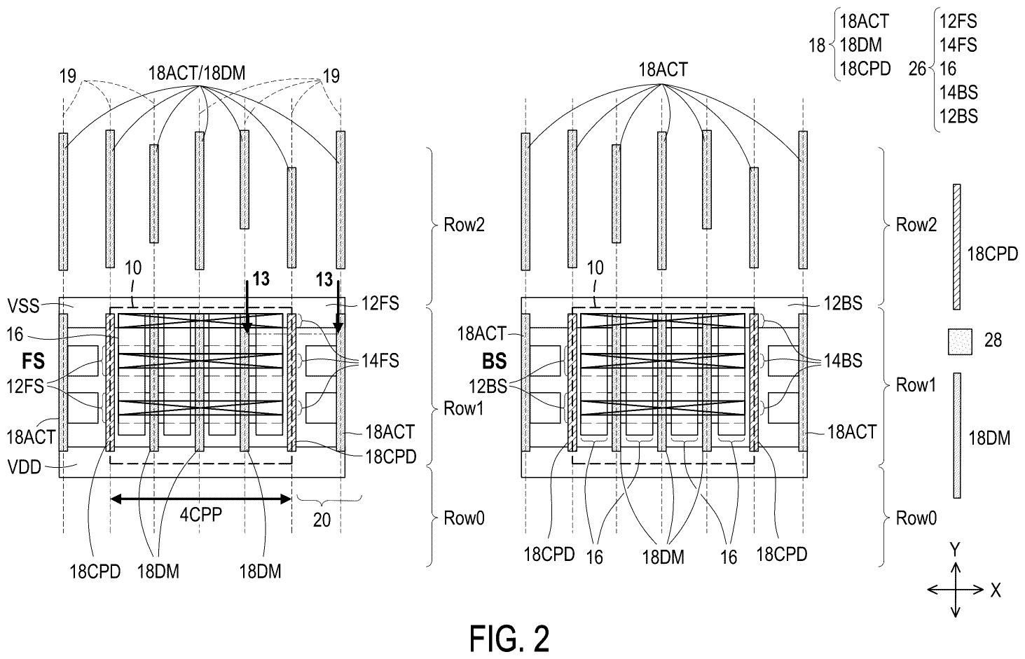

FIG. 1 illustrates a perspective view of some portions of a front-and-back interconnect structure 26, which may be a portion of a power tap cell 10 (FIG. 2) in accordance with some embodiments. Power tap cell 10 is used for conducting power (VDD and/or VSS) between the front side and the backside of a wafer (and/or device die). The wafer/die may include CFET devices, as will be discussed in detail hereinafter. The front-and-back interconnect structure 26 includes front-side power lines 12FS, which may be VDD lines or VSS lines, front-side vias 14FS underlying front-side power lines 12FS, backside power lines 12BS, and backside vias 14BS over backside power lines 12BS. Front-side power lines 12FS and backside power lines 12BS are either VDD lines or VSS lines, depending on the circuit design.

Power tap cell 10 (FIG. 2) may be used for connecting power from backside to front side, or from front side to backside of the substrate in a wafer/die, depending on the circuit design. In accordance with some example embodiments, the CFET devices formed in the wafer/die have NFET devices over PFET devices, and wider VSS lines may be formed on the backside for long-range power routing. Accordingly, VSS is conducted from the backside to the front side, so that power may be provided to the devices that use the power. VDD, on the other hand, may be formed on the front side for long-range power routing, and may not be conducted to the backside through power tap cells. In accordance with alternative embodiments in which PFETs are formed over the NFET, long-range VDD may be formed on the backside, and may be conducted from the backside to the front side to provide power to the devices that need the power. In the example embodiments discussed throughout the description, the conduction of VSS from backside to the front side may be used as examples, while the discussion also applies to the routing of power VDD, and applies to the conduction of power from the front side to the backside.

It is appreciated that power tap cell 10 may include additional components such as gate-replacing structures, which are not shown in FIG. 1 for clarity. The additional components may be found referring to FIG. 2.

Again, referring to FIG. 1, a plurality of elongated deep contact plugs 16 are formed parallel to each other, and are formed between, and interconnecting, the front-side vias 14FS and backside vias 14BS. The lengthwise directions of deep contact plugs 16 are perpendicular to the lengthwise directions of power lines 12FS and 12BS and vias 14FS and 14BS. For example, the lengthwise directions of power lines 12FS and 12BS and vias 14FS and 14BS may be in the X-direction, and the lengthwise direction of deep contact plugs 16 may be in the Y-directions. Front-side vias 14FS are between, and interconnect, front-side power lines 12FS and deep contact vias 16. Backside vias 14BS are between, and interconnect, backside power lines 12BS and deep contact vias 16.

FIG. 2 illustrates a top view (layout) of a front-side (FS) structure and a top view (layout) of a backside (BS) structure of power tap cell 10 in accordance with some embodiments. The front side structure and the backside structure are shown on the left side and the right, respectively, in FIG. 2, and are marked as FS and BS, respectively. Power tap cell 10 may be placed inside one row (such as row Row1) in a plurality of parallel and abutted rows (such as rows Row0, Row1, and Row2) of circuit cells. The circuit cells may include power tap cells and other types of standard cells (such as AND cells, OR cells, NAND cells, Inverter cells, etc.). Each row includes a front-side VDD line and a front side VSS line, and may also include a backside VSS line and/or a backside VDD line. The VDD line of a row is joined with the VDD line of its abutting row, and the VSS line of a row is joined with the VSS line of another abutting row.

Power tap cell 10 is illustrated by showing its boundaries using dashed lines. It is assumed that another standard cell 20 is also in the row Row1, and is abutted to power tap cell 10. The rows may include a plurality of gate-replacing structures 18, which may include active replacement gate stacks 18ACT (metal gates) of transistors, dummy replacement gate stacks 18DM, and dielectric isolation regions 18CPD. The gate-replacing structures 18 are formed by replacing dummy gate stacks. The dielectric isolation regions 18CPD may also sometimes be referred to as Continuous Poly On Diffusion Edge (CPODE) regions or Cut Poly On Diffusion Edge (CPODE)) regions. The active dummy gate stacks 18ACT are shown schematically, and may have different lengths than illustrated, depending on the circuit design. The dummy replacement gate stacks 18DM and the dielectric isolation regions 18CPD, on the other hand, may have the same length.

In accordance with some embodiments, gate-replacing structures 18 are formed as having a uniform pitch, and are parallel to each other. Furthermore, the gate-replacing structures 18 may be formed by forming long dummy gate stacks with the uniform pitch and extending into multiple rows, and cutting long dummy gate stacks. The gate-replacing structures 18 in one row of cells thus may be aligned to (while separated from) the active (replacement) gate stacks 18ACT and dummy replacement gate stacks 18DM in the neighboring rows. Accordingly, although CPODE regions 18CPD are dielectric regions, CPODE regions 18CPD may be identified by their widths (same as the width of the active gate stacks 18ACT and dummy replacement gate stacks 18DM in neighboring rows) and their positions (aligned to the same straight and parallel lines 19).

In accordance with some embodiments, power tap cell 10 further includes dummy replacement gate stacks 18DM, which are between and parallel to CPODE regions 18CPD. Dummy replacement gate stacks 18DM and CPODE regions 18CPD collectively have a uniform pitch. In the top view, each of dummy replacement gate stacks 18DM and CPODE regions 18CPD may have an end extending to front-side power line VDD, and an opposite end extending to front-side power line VSS. It is appreciated that each of the dummy replacement gate stacks 18DM and CPODE regions 18CPD is shown in both of the front-side and the backside structure.

At least one or a plurality of deep contact plugs 16 are formed. Each between two of the gate-replacing structures 18. Deep contact plugs 16 may be formed in the same processes for forming front-side source/drain contact plugs connecting to the front-side FETs. In accordance with some embodiments, deep contact plugs 16 are elongated and having lengthwise direction parallel to the lengthwise direction (Y-direction) of gate-replacing structures 18. This has two functions. First, with deep contact plugs 16 being elongated, it may have reduced resistance and reduced contact resistance. Furthermore, elongate deep contact plugs 16 are able to be connected to more than one overlying and underlying vias and metal lines, and may be used as signal connections, as will be discussed subsequently.

Advantageously, the deep contact plugs 16 in accordance with the embodiments of the present disclosure are between gate-replacing structures 18, and do not cut the gate-replacing structures 18. Accordingly, in the power tap cell 10, there is no need to add a dummy gate stack between each CPODE region 18CPD and its nearest deep contact plug 16 to prevent the violation of design rules. The power tap cell 10 thus may be formed smaller. For example, the pitches (referred to as Contacted Poly Pitches (CPP)) of the gate-replacing structures may be used as the unit for measuring the dimensions of cells. Accordingly, in the example embodiments as shown in FIG. 2, the dimension of power tap cell 10 in the X-direction is 4 CPP, rather than 6 CPP.

Front-side vias 14FS and backside vias 14BS are also shown in the front-side structure and the backside structure, respectively, and have lengthwise directions in the X-direction. Front-side vias 14FS are underlying and overlapped by the corresponding front-side power lines 12FS. Backside vias 14BS are overlying and overlap the corresponding backside power lines 12BS.

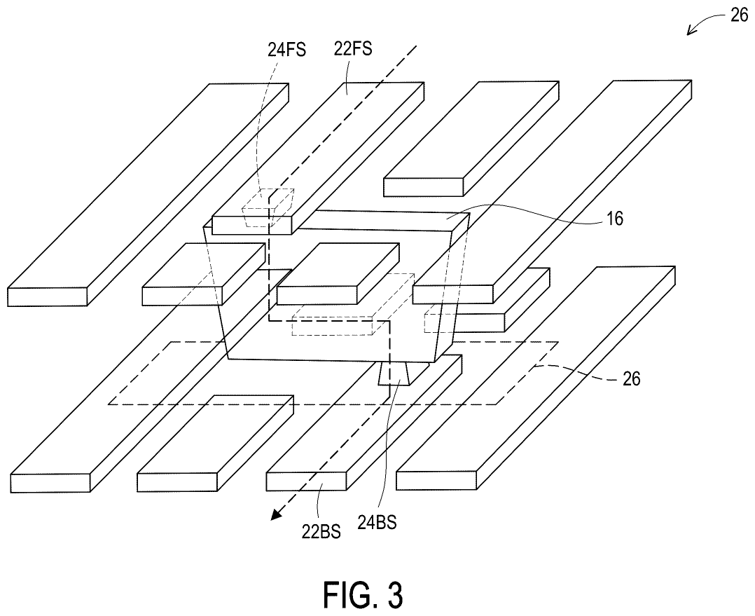

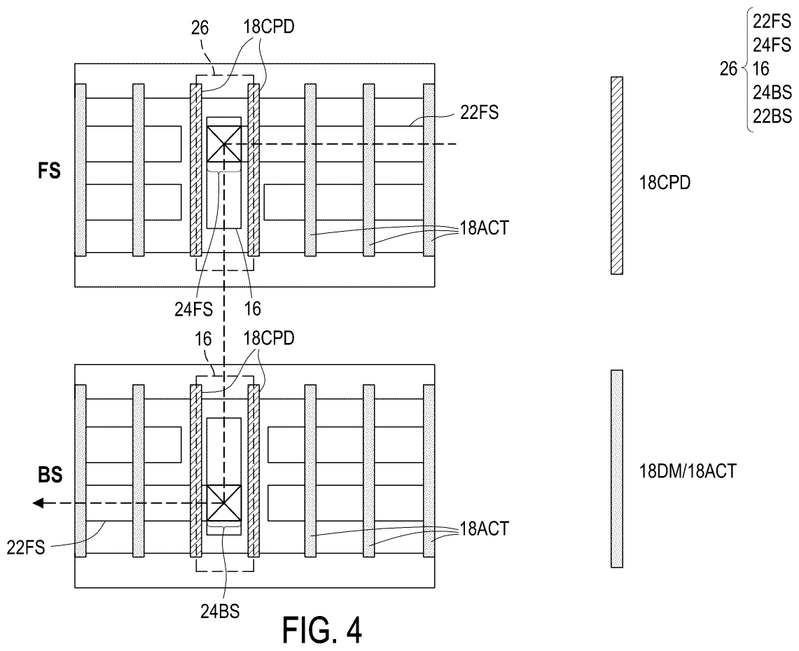

FIGS. 3 and 4 illustrate a perspective view of front-and-back interconnect structure 26 for signal connection in accordance with some embodiments. The front-and-back interconnect structure 26 includes front-side metal line 22FS, front-side via 24FS, backside metal line 22BS, and backside via 24BS. Deep contact plug 16 is between and contacts front-side via 24FS and backside via 24BS. Deep contact plug 16 may be formed in the same processes for forming front-side source/drain contact plugs of the front-side FETs, and may be formed in the same processes for forming the deep contact plug 16 in power tap cell 10. Signals may be routed from front side to the backside, or from the backside to the front side, of the respective die through front-and-back interconnect structure 26.

FIG. 4 illustrates the front-side (FS) structure and the backside (BS) structure of the front-and-back interconnect structure 26 in accordance with some embodiments. The signal interconnect structure 26 may also be formed as a standard cell. Again, gate-replacing structures 18 (including 18CPD and 18ACT) as illustrated are formed as parallel to each other and have a uniform pitch. The active dummy gate stacks 18ACT are shown schematically, and may have different lengths than illustrated, depending on the circuit design. Front-and-back interconnect structure 26 may be inside a standard cell 20 or any other circuit, or may be between two cells such as two standard cells and/or power tap cells.

Similarly, deep contact plug 16 is elongated, and may be formed between two CPODEs 18CPD. Since deep contact plug 16 does not cut any gate-replacing structure 18, CPODE 18CPD may be formed immediately next to deep contact plug 16 without violating design rules, without the need of adding a dummy replacement gate stack 18DM in between.

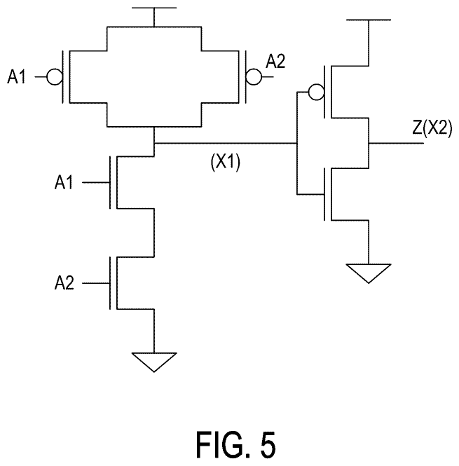

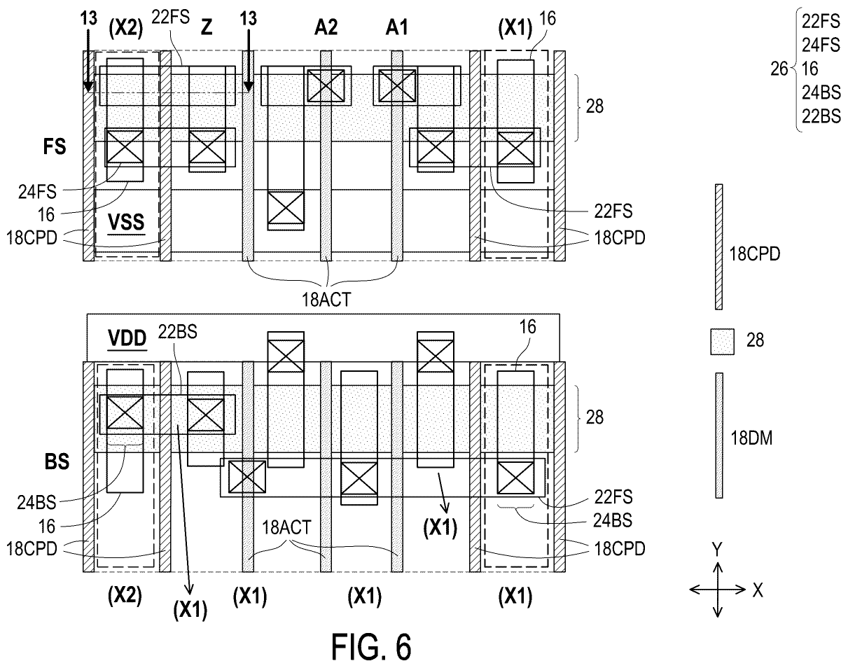

FIG. 5 illustrates a circuit diagram of an AND gate in accordance with some embodiments, with some nodes such as A1, A2, X1 and X2 being marked. FIG. 6 illustrates an example front-side structure and backside structure of the AND gate in accordance with some embodiments.

In FIG. 6, two deep contact plugs 16 are formed, each being used for routing signals on one of the nodes X1 and X2 between the front side and the backside of the respective substrate. Each of deep contact plugs 16 is elongated, and is formed between a pair of CPODE regions 18CPD. Similarly, the front-and-back routing is through the deep contact plugs 16 and the overlying front-side metal lines 22FS, front-side vias 24FS, backside metal lines 22BS, and backside vias 24BS. Active region 28, with some parts forming the channel regions of the transistors (which may include CFETs), is also illustrated, and have lengthwise direction parallel to the X-direction. Active gate stacks 18ACT cross over active region 28 to form respective transistors.

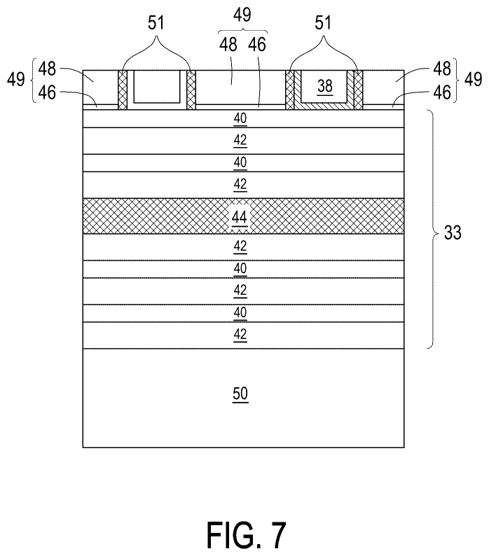

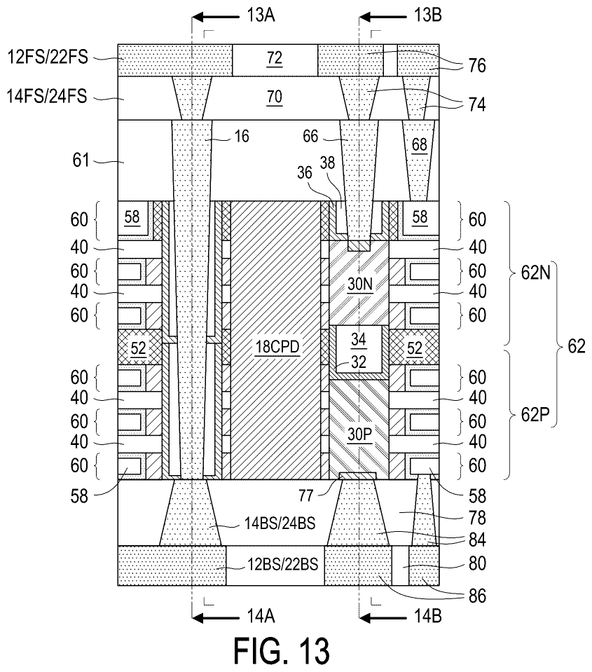

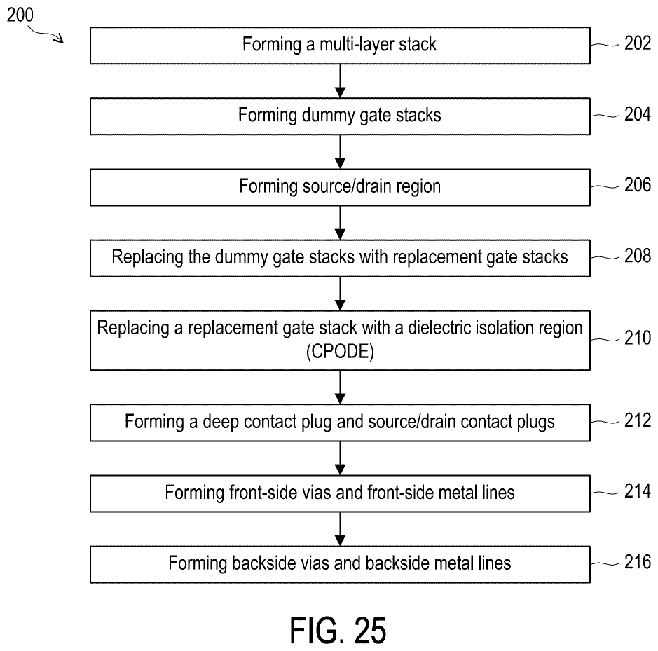

FIGS. 7 through 13 illustrate the cross-sectional views of intermediate stages in the formation of a front-and-back interconnect structure (either for power or signal) in accordance with some embodiments. The corresponding processes are also reflected schematically in the process flow 200 as shown in FIG. 25. The cross-sectional view as shown in FIG. 13 may be obtained from the cross-section 13-13 shown in FIG. 6, except that a single CPODE region 18CPD is shown in FIG. 13, while in FIG. 6, another CPODE region 18CPD (rather than a dummy gate stack or an active gate stack) is formed on the leftmost side of the structure. The cross-sectional view shown in FIG. 13 may also be obtained from the cross-section 13-13 shown in FIG. 2, except that the active region 28 as shown in FIG. 13.

FIG. 7 illustrates an intermediate structure. The formation of the structure is briefly discussed as follows. First, semiconductor substrate 50 is provided. Semiconductor substrate 50 may be a silicon substrate, or may be formed of other semiconductor substrate materials. A multi-layer stack is formed over semiconductor substrate 50. The respective process is illustrated as process 202 in the process flow 200 as shown in FIG. 25. In accordance with some embodiments, the multi-layer stack may include semiconductor layers 40, sacrificial semiconductor layers 42, and sacrificial semiconductor layer 44. Sacrificial semiconductor layer 44 separates a plurality of underlying semiconductor layers 40 and sacrificial semiconductor layers 42 from a plurality of overlying semiconductor layers 40 and sacrificial semiconductor layers 42.

In accordance with some embodiments, semiconductor layers 40 are formed of or comprise silicon (which may be free from germanium or may include a small amount of germanium, for example, less than about 10 percent). Sacrificial semiconductor layers 42 are formed of or comprise silicon germanium, for example, with a germanium atomic percentage in a range between about 30 percent and about 60 percent). Sacrificial semiconductor layer 44 may be formed of germanium (free from silicon), or may comprise silicon germanium having a higher germanium atomic percentage than sacrificial semiconductor layers 42. For example, the germanium atomic percentage of sacrificial semiconductor layer 44 may be in a range between about 70 percent and about 100 percent. The multi-layer stack is patterned to form a plurality of elongated fins 33, which are also multi-layer stacks.

Next, as also shown in FIG. 7, dummy gate stacks 49 are formed over and on the sidewalls of the elongated fins 33. The respective process is illustrated as process 204 in the process flow 200 as shown in FIG. 25. Dummy gate stacks 49 may include dummy gate dielectric 46 and dummy gate electrode 48 over dummy gate dielectric 46. Dummy gate dielectric 46 may be formed of or comprise silicon oxide. Dummy gate electrode 48 may be formed of or comprise polysilicon, amorphous silicon or the like. Accordingly, dummy gate stacks 49 are also referred to as poly gates. The gate-replacing structures 18, which includes active gate stacks 18ACT, dummy replacement gate stacks 18DM, and CPODE regions 18CPD, are the replacement structures of the poly gate stacks, which are formed by replacing corresponding portions of the dummy gate stacks 49 with corresponding structures and materials, as discussed in subsequent paragraphs. Gate spacers 51 are formed on the sidewalls of dummy gate stacks 49.

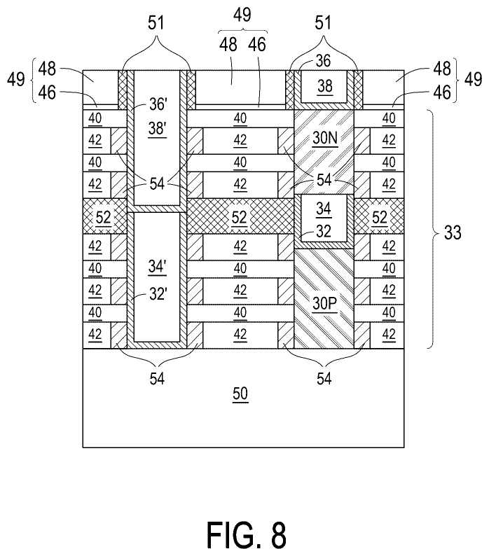

FIG. 8 illustrates the formation of some features in elongated semiconductor fins 33. In accordance with some embodiments, portions of the elongated fins 33 are etched to form openings, which are between (and lower than) neighboring dummy gate stacks 49. Inner spacers 54 are then formed. The formation process may include performing an isotropic etching process to laterally recess sacrificial semiconductor layers 42 and to form lateral recesses. Another dielectric material is deposited through a conformal deposition process such as ALD, CVD, or the like, followed by an etching process to remove excess portions of the dielectric material. The remaining portions of the dielectric material remaining in the lateral recesses form inner spacers 54.

Dielectric isolation layer 52 is also formed. In the formation process, sacrificial semiconductor layer 44 is first removed through an isotropic etching process. A dielectric material is deposited through a conformal deposition process such as Atomic Layer Deposition (ALD), Chemical Vapor Deposition (CVD), or the like to fill the void left by the removed sacrificial semiconductor layer 44. An etching process is then performed to remove the portions of the dielectric layer on the sidewalls of semiconductor layers 40 and inner spacers 54. The remaining portions of the dielectric material form dielectric isolation layer 52.

The material of dielectric isolation layer 52 may be the same as or different from the material of inner spacers 54. The materials of dielectric isolation layer 52 and inner spacers 54 may be selected from SiO, SiN, SiON, SiOC, SiOCN, or the like. In accordance with alternative embodiments, dielectric isolation layer 52 and inner spacers 54 may be formed using common processes.

P-type source/drain regions 30P and n-type source/drain regions 30N are formed in some of the openings, and act as the source/drain regions of a PFET and an NFET, respectively. The respective process is illustrated as process 206 in the process flow 200 as shown in FIG. 25. Source/drain region(s) may refer to a source or a drain, individually or collectively dependent upon the context. The formation processes include epitaxy processes. Contact Etch Stop layer (CESL) 32 and Inter-layer Dielectric 34 are formed to separate p-type source/drain regions 30P from n-type source/drain regions 30N. CESL 36 and ILD 38 are formed over n-type source/drain regions 30N.

In addition, CESL 32′ and ILD 38′, and CESL 36′ and ILD 38′ are also formed in one of the openings. CESL 32′ and ILD 34′ may be formed in the same processes as the formation of CESL 32 and ILD 34, respectively. CESL 36′ and ILD 38′ may be formed in the same processes as the formation of CESL 36 and ILD 38, respectively.

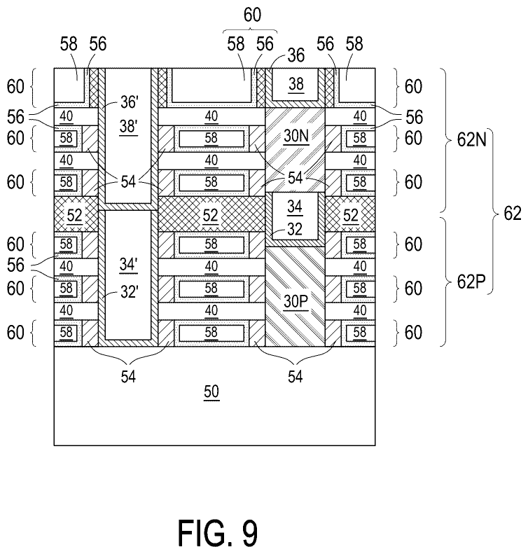

FIG. 9 illustrates the formation of replacement gate stacks 60. In accordance with some embodiments, the dummy gate stacks 49 as shown in FIG. 8 are removed to form openings. The sidewalls of the sacrificial semiconductor layers 42 are exposed, wherein the sidewalls can be viewed in the cross-section cutting through dummy gate stacks 49.

Replacement gate stacks 60 are then formed. The respective process is illustrated as process 208 in the process flow 200 as shown in FIG. 25. The formation process may include removing sacrificial semiconductor layers 42 through etching, depositing gate dielectric layers, depositing gate electrode layers, and performing a planarization process to remove excess portions of the deposited layers. A PFET 62P and an NFET 62N are then formed, which are collectively referred to as a CFET 62. The gate electrodes of PFET 62P and NFET 62N may comprise different materials, and the replacement gate stacks of PFET 62P and NFET 62N may be formed in different processes or common processes, which are not discussed in detail herein.

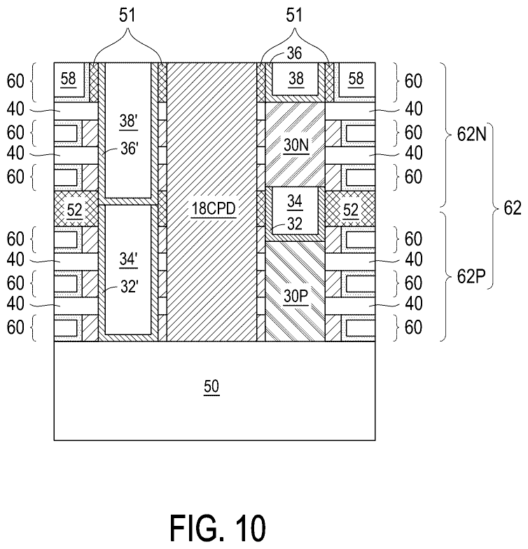

One of the replacement gate stacks 60 in the middle of the illustrated structure is then etched to form CPODE region 18CPD, as is shown in FIG. 10. The respective process is illustrated as process 210 in the process flow 200 as shown in FIG. 25. The formation process may include performing etching processes to remove the replacement gate stack 60, semiconductor layers 40, dielectric isolation region 52, and filling the corresponding trench with a dielectric layer(s). A planarization process is then performed, and the remaining portion of the dielectric layer is referred to as CPODE region 18CPD. The material of the CPODE region 18CPD may include SiO, SiN, SiCN, SiOCN, or the like, combinations thereof, and/or multi-layers thereof.

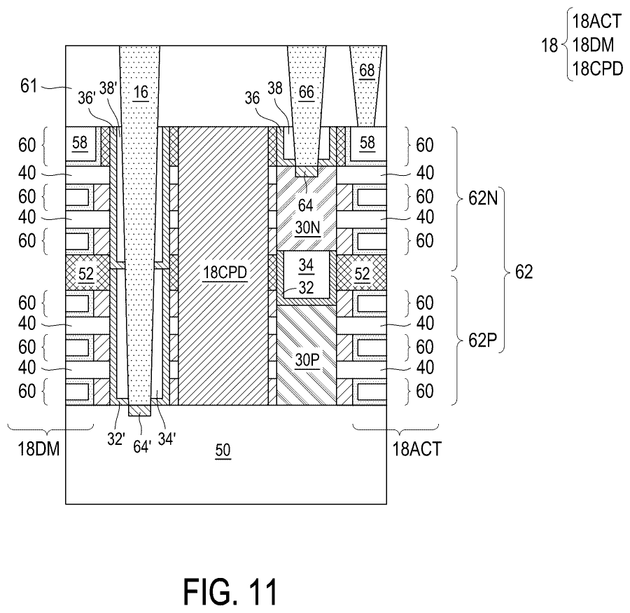

FIG. 11 illustrates the formation of ILD 61, deep contact plug 16, source/drain contact plug 66, gate contact plug 68, and source/drain silicide region 64. The respective process is illustrated as process 212 in the process flow 200 as shown in FIG. 25. In accordance with some embodiments, the formation process includes etching-through ILD 61, ILD 38, CESL 36, ILD 38′, CESL 36′, ILD 34′, and possibly CESL 32′ to form openings, wherein the underlying semiconductor regions such as source/drain regions 30N (and possibly semiconductor substrate 50) may are exposed. A metal layer is then deposited, followed by an anneal process to form source/drain silicide regions 64 (and possibly 64′). The unreacted portions of the metal layer may then be removed, and a conductive material is filled into the remaining portion of the openings to form deep contact plug 16, source/drain contact plug 66, and gate contact plug 68.

Alternatively, in the formation of the deep openings, the etching process may be stopped on a bottom portion of CESL 32′. Accordingly, dummy silicide region 64′ is not formed, and deep contact plug 16 has a bottom surface contacting a top surface of the bottom portion of CESL 32′.

FIG. 11 also illustrates the formation of gate contact plug 68, which extends into ILD 61 and lands on the top surface of gate stack 60. Accordingly, the respective gate stack 60 is an active gate stack (of the corresponding NFET 62N), and is also referred to as active gate stack 18ACT. In accordance with some example embodiments, the gate stack 60 on the left side of deep contact plug 16 does not have any gate contact plug connecting to it, and is electrically floating. Accordingly, the corresponding gate stack 60 is also referred to as dummy replacement gate stack 18DM. FIG. 11 thus illustrates the examples of each of CPODE 18CPD, dummy replacement gate 18DM, and active gate stack 18ACT, which are collectively referred to as gate-replacing structures 18.

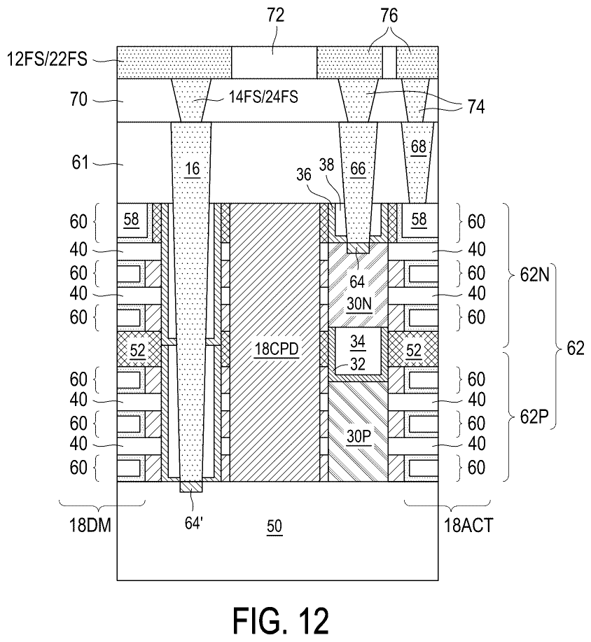

FIG. 12 illustrates the formation of a front side interconnect structure including ILD 70 and Inter-Metal Dielectric (IMD) 72. The respective process is illustrated as process 214 in the process flow 200 as shown in FIG. 25. IMD 72 may be formed of a low-k dielectric material, which may be a carbon-containing dielectric material. Vias 74 are formed to electrically connect to the source/drain regions 30N and gate electrode 58. Furthermore, front-side via 14FS/24FS is formed, which may be front-side via 24FS (FIGS. 3 and 4), or may be front-side via 14FS (FIGS. 1 and 2), depending on whether the respective deep contact plug 16 is used in a power tap cell or for signal routing. Metal lines 12FS/22FS and 76 (which are referred to as Mo metal lines) are also formed. Metal line 12FS/22FS may be a VDD line or a VSS line connecting to via 14FS, or a signal line connecting to via 24FS. Also, metal lines 76 are connected to the source/drain regions 30N and gate electrode 58.

FIG. 13 illustrates the formation of a backside interconnect structure. The respective process is illustrated as process 216 in the process flow 200 as shown in FIG. 25. The backside interconnect structure includes dielectric layers 78 and 80. Vias 84 are formed to electrically connect to the source/drain regions 30P and gate electrode 58. Furthermore, backside via 14BS/24BS is formed, which may be backside via 14FS (FIGS. 1 and 2), or may be backside via 24FS (FIGS. 3 and 4), depending on whether the respective deep contact plug 16 is used in a power tap cell or for signal routing. If deep contact plug 16 lands on CESL 32′, backside via 14BS/24BS will penetrate through CESL 32′ in order to connect to deep contact plug 16. Source/drain silicide region 77 may also be formed.

Metal lines 12BS/22BS and 86 (which are referred to as backside Mo metal lines) are also formed. Metal line 12BS/22BS may include a VDD line or a VSS line connecting to vias 24BS, or a signal line connecting to via 14BS. Also, metal lines 86 are electrically connected to the source/drain regions 30N and the gate electrode 58 of the PFET 62P.

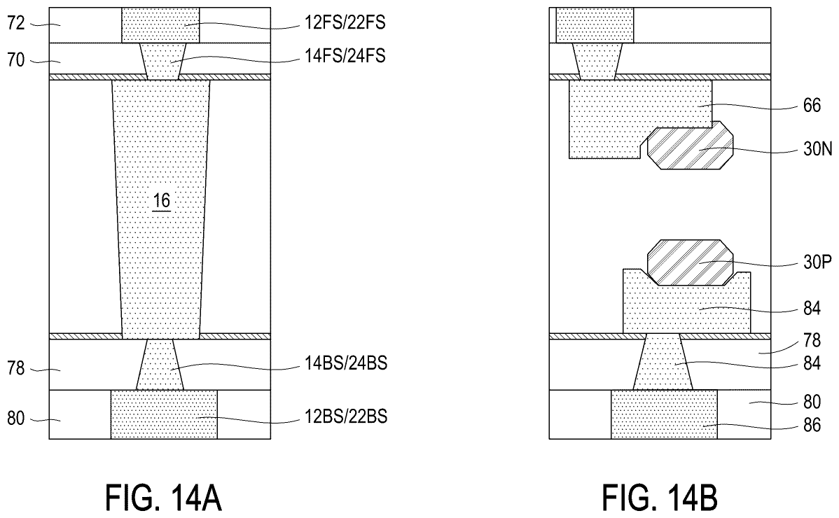

FIGS. 14A and 14B illustrate the cross-sections 14A-14A and 14B-14B as in FIG. 13. The example features are marked for references.

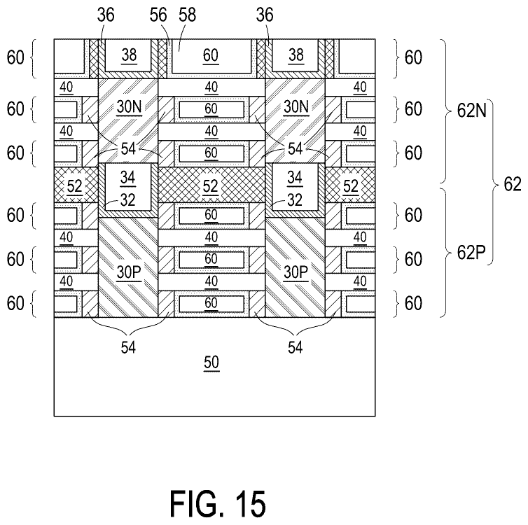

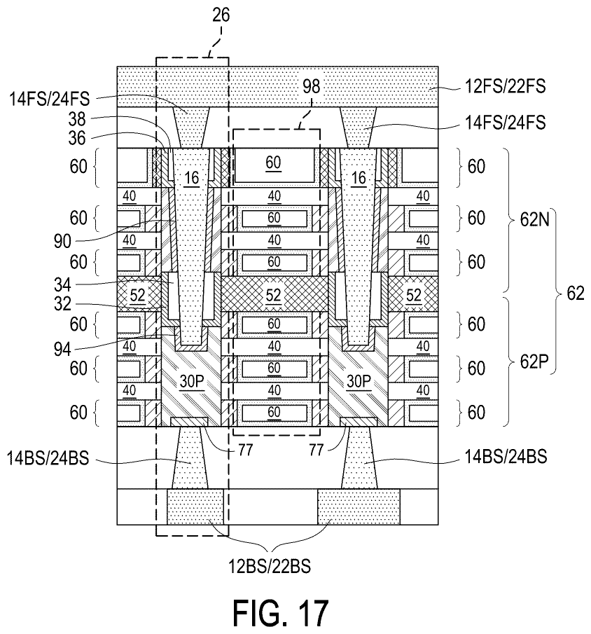

FIGS. 15 through 17 illustrate the formation of a front-and-back interconnect structure 26 in accordance with alternative embodiments. The front-and-back interconnect structure 16 as shown in FIG. 17 may be parts of the power tap cell 10 as shown in FIGS. 1 and 2, or may be parts of a signal connection as shown in FIGS. 3 and 4. It is appreciated that the structure formed through these processes may be in the same device wafer/die, and may share same processes as, the structure formed in FIGS. 6 through 13.

Referring to FIG. 15, a structure similar to the structure shown in FIG. 9 is formed. The formation processes may be realized by referring to the discussion of FIGS. 7, 8, and 9, and are not repeated herein. In accordance with some embodiments, in order to form the interconnect structure, source/drain regions 30P, 30N, CESL 32, ILD 34, CESL 36, and ILD 38 are formed.

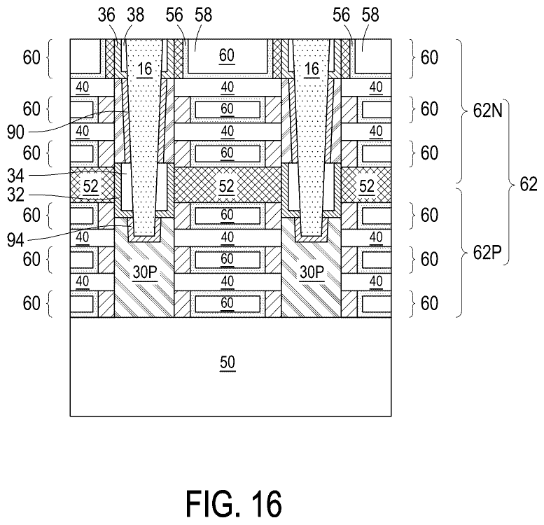

FIG. 16 illustrates the formation of deep contact plugs 16 and silicide regions 90 and 94. In accordance with some embodiments, the formation process includes etching-through ILD 38, CESL 36, source/drain regions 30N, ILD 34, and CESL 32 to form openings. The etching process is stopped on the lower source/drain regions 30P. A metal layer is then deposited using a conformal deposition process, followed by an anneal process to form source/drain silicide regions 90 and 94. The unreacted portions of the metal layer are then removed. A conductive material is then formed to fill the remaining portions of the openings to form deep contact plugs 16. Silicide regions 90 and 94 and deep contact plugs 16 electrically interconnect source/drain regions 30P with the corresponding source/drain regions 30N.

Deep contact plugs 16 may be formed in the same process as the formation of the source/drain contact plugs 66 (FIG. 11) in accordance with some embodiments. Also, although FIG. 16 illustrates that deep contact plugs 16 have top surfaces coplanar with the top surfaces of replacement gates stacks 60, the top surfaces of deep contact plugs 16 may also extend into ILD 61, same as shown in FIG. 13.

Referring to FIG. 17, a front-side structure and a backside structure are formed, which are similar to what are shown in FIG. 13. The structure shown in FIG. 17 includes front-and-back interconnect structure 26, which includes front-side metal line 12FS/22FS, front-side via 14FS/24FS, deep contact plug 16, source/drain region 30N, silicide region 77, backside via 14BS/22BS, and backside metal line 12BS/24BS.

It is appreciated that the structures formed neighboring the front-and-back interconnect structures 26 may be different from the illustrated example embodiments. For example, the features in region 98 may be any of the dummy replacement gate stacks 18DM, active gate stacks 18ACT, and CPODE regions 18CPD, which example features are shown in FIG. 13.

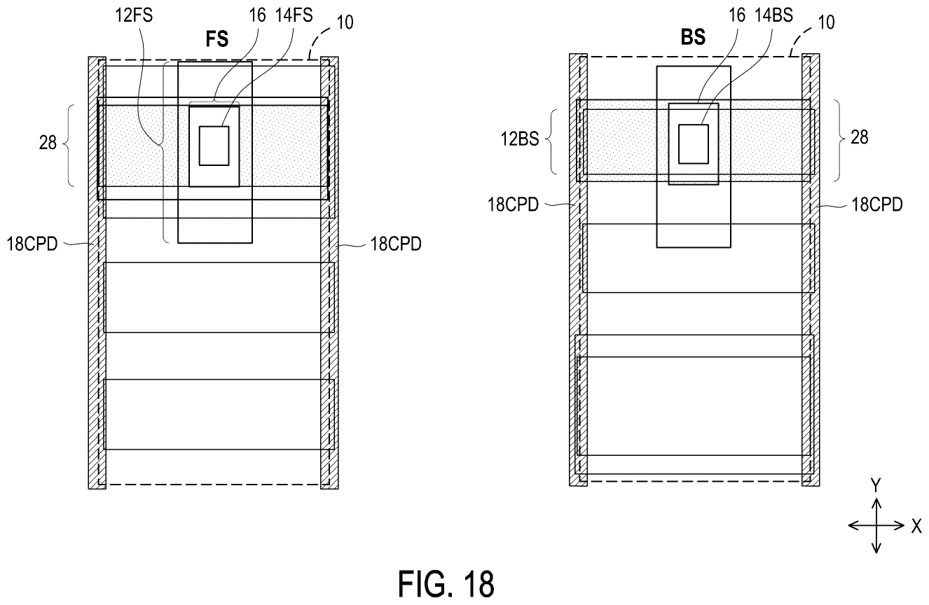

FIG. 18 illustrates some features in the front-side structure and the backside structure of an example power tap cell 10, which is formed using the embodiments as shown in FIG. 17. The illustrated example is referred to as a 1-CPP power tap cell since its dimension in the X-direction is 1 CPP. The front-side metal line 12FS, front-side via 14FS, deep contact plug 16, backside via 14BS, and backside metal line 12BS are illustrated, and may be used for connecting VSS line or VDD line.

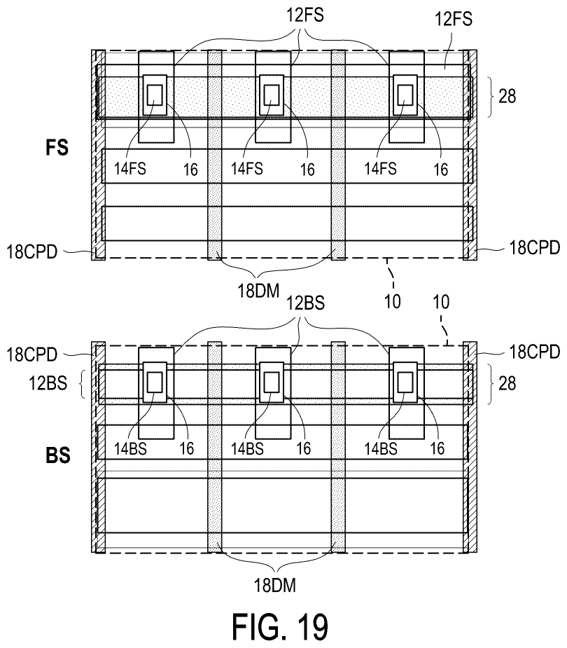

FIG. 19 illustrates the front-side structure and the backside structure of an example power tap cell 10 formed using the embodiments as shown in FIG. 17. The illustrated example is referred to as a 3-CPP power tap cell since its dimension in the X-direction is 3 CPP. Dummy replacement gate stacks 18DM are formed inside power tap cell 10 to separate deep contact plugs 16.

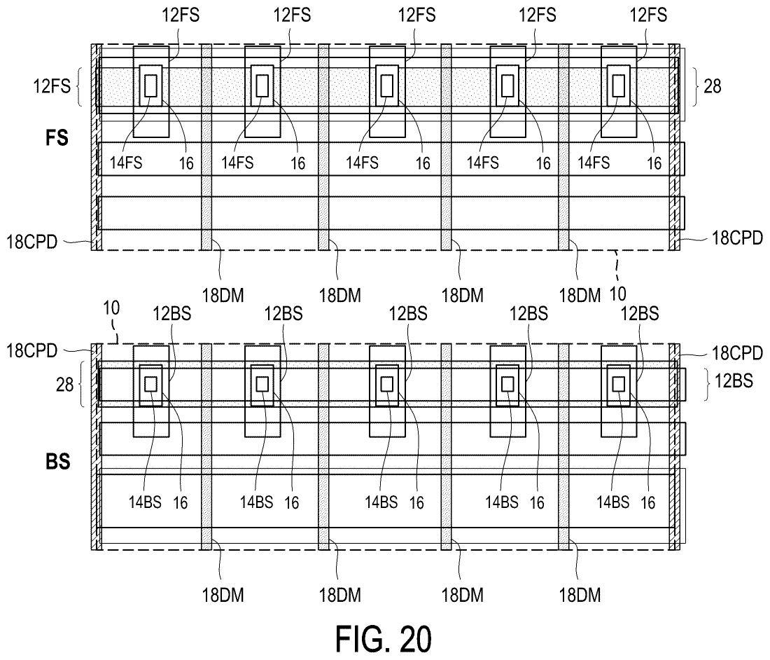

FIG. 20 illustrates the front-side structure and the backside structure of an example power tap cell 10 formed using the embodiments as shown in FIG. 17. The illustrated example is referred to as a 5-CPP power tap cell since its dimension in the X-direction is 5 CPP.

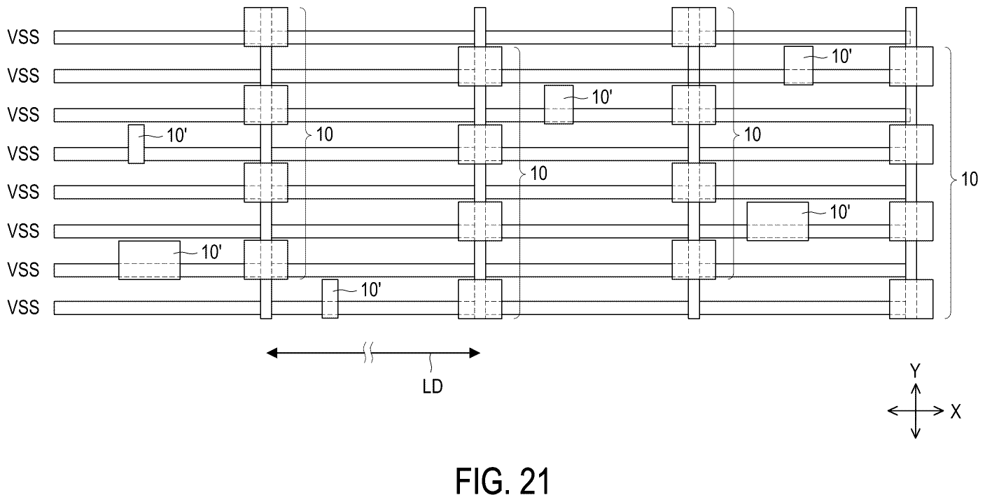

FIGS. 21 through 24 illustrate some example usage of the embodiments as discussed above. FIG. 21 illustrates the top view (layout) of a plurality of power lines extending in the X-direction. The illustrated example power lines are VSS lines, they may also be VDD lines in accordance with alternative embodiments. A plurality of power tap cells are formed with a periodic pattern. For example, for each of the horizontal VSS lines, and for a fix distance LD (such as 24 CPP, 36 CPP, 48 CPP, 60 CPP, or the like), a power tap cell 10 is formed to conduct power from backside to the front side (assuming the backside VSS is used for long-range routing and are wider than the front-side VSS lines). Power tap cell 10 may have structures and sizes identical to each other. A plurality of gate-replacing structures may also be formed for each CPP, and the plurality of gate-replacing structures are not shown. The power tap cells 10 on neighboring VSS lines are interlaced.

It is appreciated that after the design of circuits, some empty spaces may be left without having cells placed. Accordingly, more power tap cells (denoted as 10′) may be formed in the empty spaces. This increases the number of power tap cells, and reduces the voltage drop on the power lines. Also, depending on the available spaces, the power tap cells 10′ may have sizes the same as or different from each other, and the same as or different from the periodically placed power tap cells 10. For example, power tap cells 10 and 10′ may have any dimensions equal to 1 CPP, 2 CPP, 3 CPP, 4 CPP, 5 CPP, or any other size in any combination.

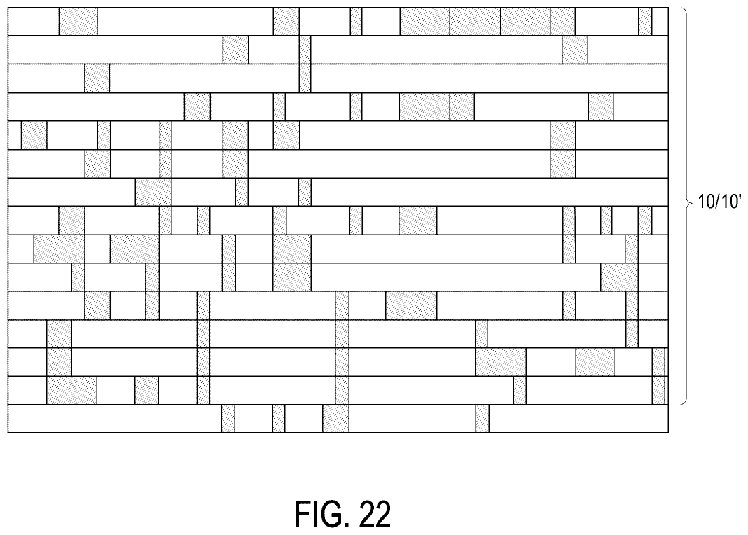

FIG. 22 schematically illustrates the placed power tap cells 10 and 10′ in a plurality of rows of cells in accordance with some embodiments. In accordance with some embodiments, the standard cells placed for integrated circuits may have significant amount of areas left, which may be, for example, up to about 20 percent or higher of the chip area. The left empty space may be used for forming power tap cells 10 and 10′.

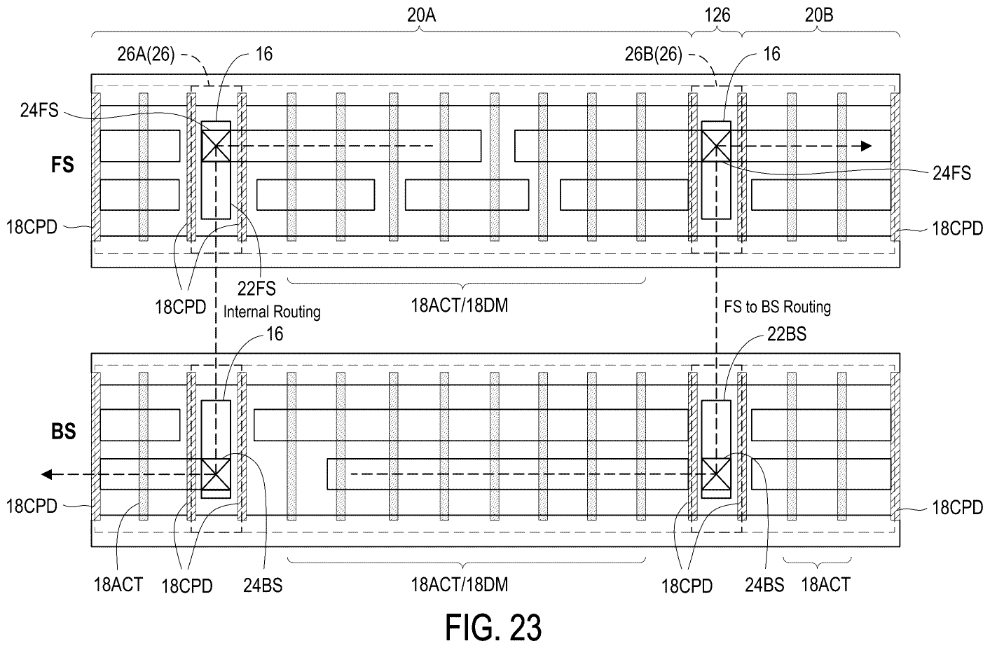

FIG. 23 schematically illustrates an embodiment, in which the front-and-back interconnect structures 26 may be used for inter-cell signal routing and inner-cell signal routing. For example, front-and-back interconnect structures 26A is used for the inner-cell routing, in which signals are routed from the front side to the backside of the same cell 20A. Front-and-back interconnect structure 26B, which may be inside a standard cell 126 specifically for signal routing, is used for the inter-cell routing. Power or signal may be routed from the backside (or front side) of cell 20A to the front side (or backside) of cell 20B through the front-and-back interconnect structures 26B in cell 126.

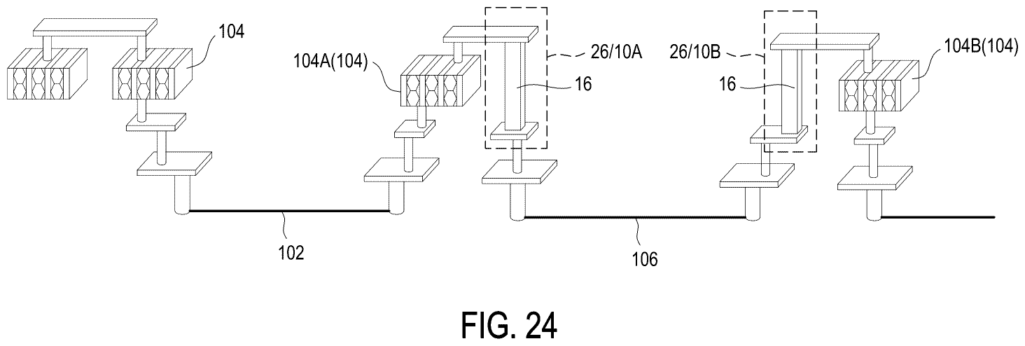

FIG. 24 illustrates an embodiment in which power tap cells 10 are used for routing power, which is gated by driver cells 104. For example, the power on long-range power line 102 may be provided to, and is gated by, driver cell 104A. The long-range power line 102 may be on the backside of the respective die. The power provided out of driver cell 104A may be routed again by power tap cell 10A to the back of the die, and put on long-range power line 106. The power on long-range power line 106 may further be conducted to the front side of the die by power tap cell 10B, and provided to driver cell 104B. Accordingly, the power tap cells 10 in accordance with the embodiments of the present application provide the flexibility of routing power on front side and back side.

In accordance with the embodiments of the present disclosure, signals may be routed using the front-and-back interconnect structures 26 from backside to front side, and from front side to back side. This provide significant flexibility in the design of circuits. For example, the input and output nodes of standard cells may be located either on the front side or the backside of the respective die in any combination, and may be used and connected to the desirable sides using the front-and-back interconnect structures 26.

The embodiments of the present disclosure have some advantageous features. By forming front-and-back interconnect structures based on the spaces between neighboring gate-replacing structures, there is no need to cut the gate-replacing structures, and power tap cells and signal routing structures may be formed smaller. Also, elongated deep contact plugs in the front-and-back interconnect structures may have reduced resistance and hence reduced voltage drop for power lines and signal lines. The elongated deep contact plugs may also be used to connect to multiple front-side vias, front-side metal lines, and/or backside vias and backside metal lines.

In accordance with some embodiments of the present disclosure, a method comprises forming a multi-layer stack comprising dummy layers and semiconductor layers located alternatingly; forming a plurality of dummy gate stacks on sidewalls and a top surface of the multi-layer stack, wherein two of the plurality of dummy gate stacks are immediately neighboring each other, and have a space in between; forming a first source/drain region and a second source/drain region in the multi-layer stack, wherein the second source/drain region overlaps the first source/drain region; replacing the plurality of dummy gate stacks with a plurality of replacement gate stacks; replacing a first one of the plurality of replacement gate stacks with a first dielectric isolation region; forming a deep contact plug in the space; forming a front-side via over the deep contact plug; and forming a back-side via under the deep contact plug, wherein the front-side via is electrically connected to the back-side via through the deep contact plug.

In an embodiment, the method further comprises forming a source/drain contact plug electrically coupling to the second source/drain region, wherein the deep contact plug and the source/drain contact plug are formed by sharing processes. In an embodiment, one of the plurality of replacement gate stacks is a dummy replacement gate stack, and wherein the deep contact plug is between, and immediately neighboring, the first dielectric isolation region and the dummy replacement gate stack. In an embodiment, the method further comprises replacing a second one of the plurality of replacement gate stacks with a second dielectric isolation region, wherein the deep contact plug is between, and immediately neighboring, the first dielectric isolation region and the second dielectric isolation region.

In an embodiment, the deep contact plug is elongated, and has a first lengthwise direction parallel to second lengthwise directions of the plurality of replacement gate stacks. In an embodiment, the method further comprises forming a third source/drain region and a fourth source/drain region in the multi-layer stack, wherein the fourth source/drain region overlaps the third source/drain region; forming an additional deep contact plug extending through the fourth source/drain region, wherein the additional deep contact plug electrically connects the fourth source/drain region to the third source/drain region; forming an additional front-side via over the fourth source/drain region; and forming an additional back-side via under the third source/drain region, wherein the additional front-side via is electrically connected to the additional back-side via through the additional deep contact plug and the third source/drain region.

In an embodiment, the method further comprises forming a source/drain contact plug electrically coupling to the second source/drain region, wherein the additional deep contact plug and the source/drain contact plug are formed with shared processes. In an embodiment, the deep contact plug and the first dielectric isolation region form parts of a power tap cell. In an embodiment, the power tap cell comprises a plurality of gate-replacing structures selected from the group consisting of dielectric isolation regions and dummy replacement gate stacks, with the plurality of gate-replacing structures having equal lengths and a uniform pitch. In an embodiment, the deep contact plug forms a part of a signal connection between a front side and a backside of a device die.

In accordance with some embodiments of the present disclosure, a structure comprises a plurality of gate-replacing structures having equal lengths and a uniform pitch, wherein the plurality of gate-replacing structures are selected from the group consisting of dielectric isolation regions, dummy replacement gate stacks, and active replacement gate stacks; a deep contact plug between two neighboring ones of the plurality of gate-replacing structures; a CFET device, wherein the deep contact plug extends from a top surface level to a bottom surface level of the CFET device; a front-side via over the deep contact plug and higher than the CFET device; and a back-side via under the deep contact plug and lower than the CFET device, wherein the front-side via is electrically connected to the back-side via through the deep contact plug.

In an embodiment, in a top view of the structure, the deep contact plug is elongated, with a first lengthwise direction of the deep contact plug being parallel to second lengthwise directions of the plurality of gate-replacing structures. In an embodiment, the plurality of gate-replacing structures comprise a dummy gate stack and a dielectric region, and wherein the deep contact plug is between, and immediately neighboring, the dielectric region and the dummy gate stack, and wherein in a top view of the structure, the dummy gate stack and the dielectric region have a same length. In an embodiment, the plurality of gate-replacing structures comprise the dummy replacement gate stacks; and the dielectric isolation regions, wherein the dielectric isolation regions have equal widths as the dummy replacement gate stacks. In an embodiment, the structure further comprises a pair of gate spacers contacting opposing sidewalls of one of the dielectric isolation regions.

In an embodiment, the structure further comprises an inter-layer dielectric over and in contact with the pair of gate spacers and the dielectric isolation regions. In an embodiment, the structure further comprises a first source/drain region and a second source/drain region overlapping the first source/drain region; an additional deep contact plug extending through the second source/drain region, wherein the additional deep contact plug electrically connects the second source/drain region to the first source/drain region; an additional front-side via over the second source/drain region; and an additional back-side via under the first source/drain region, wherein the additional front-side via is electrically connected to the additional back-side via through the additional deep contact plug and the first source/drain region.

In accordance with some embodiments of the present disclosure, a structure comprises a power tap cell comprises a first power line having a first lengthwise direction; a plurality of gate-replacing structures having second lengthwise directions perpendicular to the first lengthwise direction, wherein the plurality of gate-replacing structures are selected from the group consisting of dielectric isolation regions, dummy replacement gate stacks, and combinations thereof, and wherein the plurality of gate-replacing structures have a uniform pitch; a plurality of deep contact plugs, each being between two neighboring ones of the plurality of gate-replacing structures, wherein the plurality of deep contact plugs have third lengthwise directions parallel to the second lengthwise directions; and a second power line having the first lengthwise direction, wherein the first power line is electrically connected to the second power line through the plurality of deep contact plugs.

In an embodiment, the structure further comprises a plurality of CFET devices, wherein the plurality of deep contact plugs extend at least from top surface levels to bottom surface levels of the plurality of CFET devices. In an embodiment, the plurality of CFET devices comprise a plurality of replacement gate stacks, and wherein the plurality of gate-replacing structures and the plurality of replacement gate stacks are aligned to straight lines that have the uniform pitch.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a multi-layer stack comprising dummy layers and semiconductor layers located alternatingly;
forming a plurality of dummy gate stacks on sidewalls and a top surface of the multi-layer stack, wherein two of the plurality of dummy gate stacks are immediately neighboring each other, and have a space in between;
forming a first source/drain region and a second source/drain region in the multi-layer stack, wherein the second source/drain region overlaps the first source/drain region;
replacing the plurality of dummy gate stacks with a plurality of replacement gate stacks;
replacing a first one of the plurality of replacement gate stacks with a first dielectric isolation region;
forming a deep contact plug in the space;
forming a front-side via over the deep contact plug;
forming a back-side via under the deep contact plug, wherein the front-side via is electrically connected to the back-side via through the deep contact plug; and
forming a source/drain contact plug electrically coupling to the second source/drain region, wherein the deep contact plug and the source/drain contact plug are formed by sharing processes, wherein one of the plurality of replacement gate stacks is a dummy replacement gate stack, and wherein the deep contact plug is between, and immediately neighboring, the first dielectric isolation region and the dummy replacement gate stack.
